(19) United States
(12) Patent Application Publication
(10) Pub. No.: US 2018/0351020 A1
(43) Pub. Date: Dec. 6, 2018

(54) STACK-TYPE MULTI-JUNCTION SOLAR CELL

(71) Applicant: AZUR SPACE SOLAR POWER GMBH, Heilbronn (DE)

(72) Inventors: Wolfgang Guter, Stuttgart (DE); Christoph Peper, Hannover (DE)

(73) Assignee: AZUR SPACE SOLAR POWER GMBH, Heilbronn (DE)

(21) Appl. No.: 16/059,664

(22) Filed: Aug. 9, 2018

Related U.S. Application Data
(63) Continuation of application No. PCT/EP2017/000130, filed on Feb. 2, 2017.

(30) Foreign Application Priority Data
Feb. 9, 2016 (DE) 10 2016 001 386.9

(51) Int. Cl. H01L 31/0687; H01L 31/0304; H02S 40/34

(52) U.S. Cl. CPC H01L 31/0687; H02S 40/34; H01L 31/03046

(57) ABSTRACT

A stacked multi-junction solar cell having a first subcell with a first band gap and a first thickness, and an additional first subcell with an additional first band gap and an additional first thickness. Each of the subcells have an emitter and a base, and a tunnel diode formed between the subcells. Light radiation passes through the first subcell before the additional first subcell. The first band gap is larger than the additional first band gap by a maximum of 0.1 eV, or the first band gap is larger than the additional first band gap by a maximum of 0.07 eV, or the first band gap is larger than the additional first band gap by a maximum of 0.04 eV, or the first band gap is larger than the additional first band gap by a maximum of 0.02 eV, or the first band gap is equal in size to the additional first band gap.

This nonprovisional application is a continuation of International Application No. PCT/EP2017/000130, which was filed on Feb. 2, 2017, and which claims priority to German Patent Application No. 10 2016 001 386.9, which was filed in Germany on Feb. 9, 2016, and which are both herein incorporated by reference.

### BACKGROUND OF THE INVENTION

### Field of the Invention

The invention relates to a stacked multi-junction solar cell.

### Description of the Background Art

A solar cell arrangement is known from WO 2013 107 628 A2. Additional arrangements of multi-junction solar cells and a multiplying of individual subcells are known from US 2010/0000136 A1, from US 2006/0048811 A1, from US 2013/0133730 A1, from US 2013/0048063 A1, and from EP 1 134 813 A2, which corresponds to U.S. Pat. No. 6,316,715.

### SUMMARY OF THE INVENTION

It is therefore an object of the present invention to provide an arrangement that advances the state of the art.

In an exemplary embodiment of the invention, a stacked multi-junction solar cell is provided, comprising a first subcell with a first band gap and a first thickness, and comprising an additional first subcell with an additional first band gap and an additional first thickness, wherein each of the subcells has an emitter and a base, and a tunnel diode is formed between the subcells, wherein the light radiation passes through the first subcell before the first additional first subcell, wherein the first band gap is larger than the additional first band gap by a maximum of 0.1 eV, or the first band gap is larger than the additional first band gap by a maximum of 0.07 eV, or the first band gap is larger than the additional first band gap by a maximum of 0.04 eV, or the first band gap is larger than the additional first band gap by a maximum of 0.02 eV, or the first band gap is equal in size to the additional first band gap.

It is a matter of course that the term multi-junction solar cell is understood to mean both monolithically integrated multi-junction solar cells and multi-junction solar cells produced by means of a wafer bonding method. It should be noted that the expression “additional first subcell” can be understood to mean a subcell with physical characteristics that are similar or identical to the first subcell, or in other words, the first subcell is more or less cloned, which is to say two half first subcells are produced. It is also a matter of course that the absorbed wavelength of the two subcells is very similar or the same. It is furthermore a matter of course that the thickness of, in particular, the first half subcell is made only half as large, at a maximum, as compared to a full first subcell, so that sufficient light of the wavelength to be absorbed still reaches the additional first subcell as well. Preferably, the thickness of the first subcell is chosen to be less than the thickness of the additional first subcell. In addition, it should be noted that III-V or II-VI multi-junction solar cells are preferably suitable for doubling. It should be noted that tripling does not further increase the efficiency of the multi-junction solar cell as compared to doubling, but instead reduces it again, because of the significantly higher number of semiconductor layers.

Doubling the subcells with nearly the same band gap does indeed initially appear, to the person skilled in the art, as though it would not achieve a higher efficiency, since the absorption ranges of the subcells are not better matched to the solar spectrum. However, investigations have shown, surprisingly, that the current is halved at a doubled voltage when the cells are doubled, by which means the series resistive losses can be reduced.

Alternatively, the multi-junction solar cell can also be operated at higher solar concentrations as a result of the lower current. In this way, the considerable share of the costs from the III-V multi-junction solar cells can be reduced, especially in the case of concentrator systems. For example, in the case of a 25 mm² multi-junction solar cell, the share in the cost of the concentrator system can be reduced by approximately 50% if the concentration can be doubled. Investigations have shown that the concentration factors can be increased from a factor of 500 to over 1000, for example.

The first thickness can differ from the additional first thickness by at least 80% or by at least 50% or by at least 20%, or the two thicknesses are identical. Preferably, the first thickness is smaller than the additional first thickness.

A second subcell with a second band gap and a second thickness can be provided. The second band gap can be smaller or larger than the first band gap by at least 0.7 eV or by at least 0.4 eV or by at least 0.2 eV. As a result, the stack of the multi-junction solar cell has a total of three subcells.

An additional second subcell can be provided, wherein the additional second subcell has an additional second band gap and an additional second thickness. The additional second band gap differs from the second band gap by a maximum of 0.1 eV or by a maximum of 0.07 eV or by a maximum of 0.04 eV or by a maximum of 0.02 eV, or the second band gap is equal in size to the additional second band gap. As a result, the stack of the multi-junction solar cell has a total of four subcells.

The second thickness can differ from the additional second thickness by at least 80% or by at least 50% or by at least 20%, or the two thicknesses are identical. Preferably, the second thickness is smaller than the additional second thickness.

A third subcell with a third band gap and a third thickness can be provided. The third band gap is smaller or larger than the second band gap by at least 0.7 eV or by at least 0.4 eV or by at least 0.2 eV. As a result, the stack of the multi-junction solar cell has a total of five subcells.

An additional third subcell can be provided, wherein the additional third subcell has an additional third band gap and an additional third thickness. The additional third band gap differs from the third band gap by a maximum of 0.1 eV or by a maximum of 0.07 eV or by a maximum of 0.04 eV or by a maximum of 0.02 eV, or the third band gap is equal in size to the additional third band gap. As a result, the stack of the multi-junction solar cell has a total of six subcells.

The third thickness can differ from the additional third thickness by at least 80% or by at least 50% or by at least 20%, or the two thicknesses are identical. Preferably, the third thickness is smaller than the additional third thickness.

The first subcell and/or the second subcell and/or the third subcell can include an (AI)InGaAs compound or an (AI)InGaP compound or an (AI)GaAs compound. It is a matter of course that, alternatively, one, two, or all three of the subcells can also be made of the aforementioned compounds. For example, the first additional subcell and/or the second additional subcell and/or the third additional subcell can include an (AI)InGaAs compound or an (AI)InGaP compound or an (AI)GaAs compound. It is a matter of course that, alternatively, one or both of the additional subcells can also be made of the aforementioned compounds. It should be noted that the element aluminum is optional, and is placed in parentheses as a result. It is a matter of course, however, that the compounds also include additional elements in other embodiments that are not mentioned.

The third and/or the third additional subcell can be a Ge-based subcell. Preferably, a metamorphic buffer is formed between the third subcell or the third additional subcell and the second subcell or the second additional subcell.

The stack of the multi-junction solar cell can include no more than 8 individual subcells in all. It is a matter of course that tunnel diodes can be formed between all subcells.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1a illutrates a triple-junction solar cell according to the prior art;

FIG. 1b illustrates an embodiment according to the invention in the form of a quintuple-junction solar cell;

FIG. 2a illutrates a triple-junction solar cell according to the prior art;

FIG. 2b illustrates an embodiment according to the invention in the form of a sextuple-junction solar cell.

### DETAILED DESCRIPTION

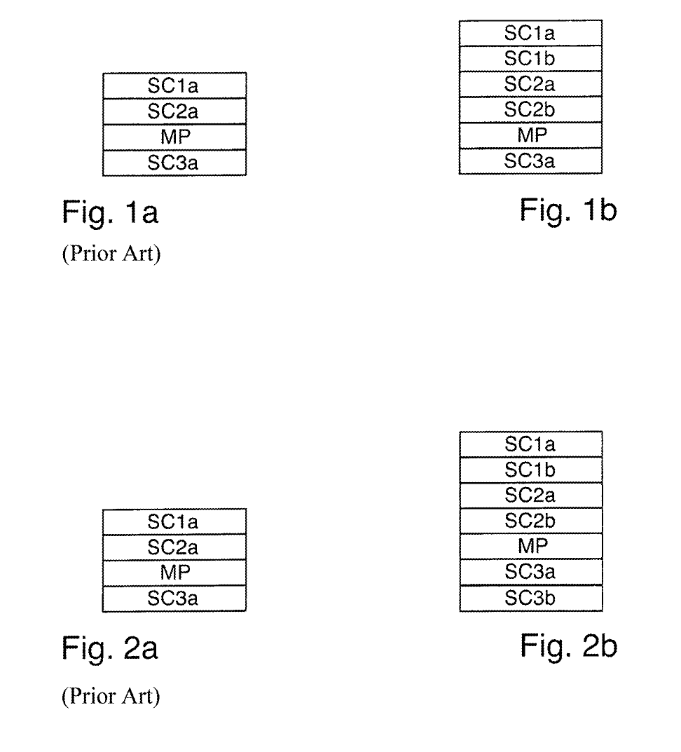

In FIG. 1a, a stacked multi-junction solar cell MS in the form of a triple-junction solar cell according to the prior art is shown. The triple-junction solar cell has a first subcell SC1a with a first band gap Eg1, and a second subcell SC2a with a second band gap Eg2, and a third subcell SC3a with a third band gap Eg3. A metamorphic buffer MP is formed between the second subcell SC2a and the third subcell SC3a. It should be noted that a triple-junction solar cell without a metamorphic buffer MP can also be used. The light first passes through the first subcell SC1a, then through the second subcell SC2a, and after that through the third subcell SC3a. A tunnel diode is formed between the subcells. The first band gap Eg1 is larger than the second band gap Eg2, and the third band gap Eg3 is smaller than the second band gap Eg2.

In FIG. 1b, a stacked multi-junction solar cell MS in the form of an embodiment according to the invention as a quintuple-junction solar cell is shown. Arranged between the first subcell SC1a and the second subcell SC2a is a first additional subcell SC1b.

The first additional subcell SC1b has an additional first band gap EG1b and an additional first thickness SD1b. Each of the subcells SC1a, SC1b has an emitter and a base.

Preferably, the first band gap Eg1a is larger than the additional first band gap Eg1b by a maximum of 0.1 eV, or the first band gap Eg1a is larger than the additional first band gap Eg1b by a maximum of 0.07 eV or by a maximum of 0.02 eV. In an alternative embodiment, the first band gap Eg1a is equal in size to the additional first band gap Eg1b.

The first subcell SC1a and the first additional subcell SC1b are made of an InGaP compound. The second subcell SC2a and the second additional subcell SC2b are made of an InGaAs compound. The third subcell SC3a is a germanium subcell.

Arranged between the second subcell SC2a and the metamorphic buffer MP is a second additional subcell SC2b. The metamorphic buffer MP includes an InGaAs compound. As a result, the quintuple-junction solar cell MS is formed.

In FIG. 2a, a triple-junction solar cell according to the prior art is shown once again. Only the differences from the embodiment in FIG. 1a are explained below. The first subcell SC1a is made of an InGaP compound, and the second subcell SC2a is made of a GaAs compound, and the third subcell SC3a is made of an InGaAs compound. The second subcell SC2a has a second band gap Eg2a and a second thickness SD2a. The first subcell SC1a has a band gap of 1.9 eV, and the second subcell SC2a has a band gap of 1.4 eV, and the third subcell SC3a has a band gap of 0.7 eV. These are exemplary values. Different triples are likewise possible for these values.

Disclosed in FIG. 2b is a multi-junction solar cell MS made from the triple-junction solar cell in FIG. 2a by the addition of an embodiment according to the invention in the form of a sextuple-junction subcell. The two first subcells SC1a and SC1b are made of an InGaP compound. The two second subcells SC2a and SC2b are made of a GaAs compound. The two third subcells SC3a and SC3b are made of an InGaAs compound.

The invention being thus described, it will be obvious that the same may be varied in many ways. Such variations are not to be regarded as a departure from the spirit and scope of the invention, and all such modifications as would be obvious to one skilled in the art are to be included within the scope of the following claims

What is claimed is:

1. A stacked multi-junction solar cell comprising:
a first subcell with a first band gap and a first thickness;
an additional first subcell with an additional first band gap and an additional first thickness;
a second subcell;
a third subcell; and
a metamorphic buffer formed between the third subcell and the second subcell, the second subcell or the third subcell includes an (AI)InGaAs compound,
wherein the second or third subcell that includes the (AI)InGaAs compound has an additional subcell,
wherein each of the first and additional first subcells have an emitter, a base, and a tunnel diode formed between the subcells,
wherein the light radiation passes through the first subcell before the additional first subcell,
wherein the first band gap is larger than the additional first band gap by a maximum of 0.1 eV or the first band gap is larger than the additional first band gap by a maximum of 0.07 eV or the first band gap is larger than the additional first band gap by a maximum of 0.04 eV or the first band gap is larger than the additional first band gap by a maximum of 0.02 eV or the first band gap is equal in size to the additional first band gap.

2. The multi-junction solar cell according to claim 1, wherein the first thickness differs from the additional first thickness by at least 80% or by at least 50% or by at least 20%, or the two thicknesses are substantially identical or identical.

3. The multi-junction solar cell according to claim 1, wherein the second subcell has a second band gap and a second thickness, and wherein the second band gap is smaller or larger than the first band gap by at least 0.7 eV or by at least 0.4 eV or by at least 0.2 eV.

4. The multi-junction solar cell according to claim 1, wherein an additional second subcell is provided, wherein the additional second subcell has an additional second band gap and an additional second thickness, wherein the additional second band gap differs from the second band gap by a maximum of 0.1 eV or by a maximum of 0.07 eV or by a maximum of 0.04 eV or by a maximum of 0.02 eV or the second band gap is substantially equal or equal in size to the additional second band gap.

5. The multi-junction solar cell according to claim 3, wherein the second thickness differs from the additional second thickness by at least 80% or by at least 50% or by at least 20%, or the two thicknesses are substantially identical or identical.

6. The multi-junction solar cell according to claim 1, wherein the third subcell has a third band gap and a third thickness, wherein the third band gap is smaller or larger than the first band gap by at least 0.7 eV or by at least 0.4 eV or by at least 0.2 eV.

7. The multi-junction solar cell according to claim 1, wherein an additional third subcell is provided, and the additional third subcell has an additional third band gap and an additional third thickness, wherein the additional third band gap differs from the third band gap by a maximum of 0.1 eV or by a maximum of 0.07 eV or by a maximum of 0.04 eV or by a maximum of 0.02 eV, or the third band gap is substantially equal or equal in size to the additional third band gap.

8. The multi-junction solar cell according to claim 6, wherein the third thickness differs from the additional third thickness by at least 80% or by at least 50% or by at least 20%, or the two thicknesses are substantially identical or identical.

9. The multi-junction solar cell according to claim 1, wherein the first subcell and/or the second subcell and/or the third subcell include an (AI)InGaAs compound or an (AI)InGaP compound or an (AI)GaAs compound or consist of an (AI)InGaAs compound or an (AI)InGaP compound or an (AI)GaAs compound.

10. The multi-junction solar cell according to claim 1, wherein the third subcell is a Ge-based subcell.

11. The multi-junction solar cell according to claim 1, wherein not more than 8 subcells or not more than 6 subcells are arranged in stacked form.
